(19) United States
(12) Patent Application Publication
(10) Pub. No.: US 2016/0017186 A1
(43) Pub. Date: Jan. 21, 2016

(54) SEALANT COMPOSITION AND SEALING SHEET OBTAINED FROM THE COMPOSITION

(71) Applicant: FURUKAWA ELECTRIC CO., LTD., Tokyo (JP)

(72) Inventors: Masami AOYAMA, Tokyo (JP); Tetsuya MIEDA, Tokyo (JP); Keiji SAITO, Tokyo (JP); Kunihiko ISHIGURO, Tokyo (JP); Toshimitsu NAKAMURA, Tokyo (JP); Naoaki MIHARA, Tokyo (JP); Takumi ASANUMA, Tokyo (JP)

(73) Assignee: FURUKAWA ELECTRIC CO., LTD., Tokyo (JP)

(21) Appl. No.: 14/867,790

(22) Filed: Sep. 28, 2015

Related U.S. Application Data
(63) Continuation of application No. PCT/JP2014/058564, filed on Mar. 26, 2014.

(30) Foreign Application Priority Data
Mar. 29, 2013 (JP) 2013-075037

(51) Int. Cl. C09J 123/08; H01L 51/52; H01L 51/00

(52) U.S. Cl. CPC C09J 123/0815; C09J 123/083; H01L 51/004; H01L 51/5246; H01L 51/5253

(57) ABSTRACT

A sealant composition being adhesive for used in electronic devices, the sealant composition including an olefin-based polymer and a tackifier, wherein the olefin-based polymer is at least one selected from an ethylene/α-olefin copolymer and an ethylene/α-olefin/non-conjugated diene copolymer, and the content of the tackifier is 10% by mass or more and 70% by mass or less in the resin composition that constitutes the sealant composition.

### CROSS-REFERENCE TO RELATED APPLICATIONS

This application is a continuation of PCT/JP2014/058564 filed on Mar. 26, 2014 which claims benefit of Japanese Patent Application No. 2013-075037 filed on Mar. 29, 2013, the subject matters of which are incorporated herein by reference in their entirety.

### TECHNICAL FIELD

The present invention relates to a sealant composition and a sealing sheet obtained from the composition.

### BACKGROUND ART

Since EL elements are self-luminescent, display devices equipped with the elements can attain high visibility. Investigations have thus been made, by utilizing such property, on high performance displays equipped with organic EL elements, namely organic EL displays, that can decrease the applied voltage compared with displays equipped with inorganic EL elements.

An organic EL element is basically configured to have a positive electrode layer, a light emitting layer, and a negative electrode layer sequentially formed on a substrate formed of glass or the like. In order to enhance the performance, functional layers may also be provided between the various layers.

An organic EL element having a configuration such as described above can be caused to emit light by passing an electric current between the positive electrode layer and the negative electrode layer. However, if moisture, impurities and the like are present around the element, the materials that constitute the element are intruded, and deterioration is caused thereby. When a display device including a deteriorated organic EL element is used, light emission defects, that is, dark spots are generated, and this leads to deterioration of visibility.

Thus, in order to shield the organic EL element from moisture, impurities and the like, an organic EL element has been disclosed (see, for example, Patent Literature 1), in which the organic EL element is provided with a transparent sealing substrate formed of glass or the like (also available is the case of a sealing can), and a viscous body containing a dehydrating agent is filled in the space produced between the organic EL element and the sealing substrate. However, it is necessary to use a dam material so as to prevent the viscous body from overflowing at the time of charging, and thus it has been infeasible to obtain a flexible organic EL device.

Furthermore, in order to obtain a flexible organic EL device, Patent Literature 2 discloses a method of sealing the device with a transparent sealing material formed from a thermoplastic resin. In this document, there is suggested a transparent sealing material for organic EL elements, which is used in an electroluminescent display panel. The display panel has a luminescent element and a sealing member; the luminescent element sequentially includes a substrate, a positive electrode layer, a light emitting layer, and a negative electrode layer; the sealing member is disposed on the light emitting surface side of the luminescent element. The transparent sealing material for organic EL elements is then characterized in that it is formed from a flexible polymer composition, and is disposed between the light emitting surface of the luminescent element and the sealing member.

### CITATION LIST

### Patent Literatures

Patent Literature 1: JP-A-2012-038660
Patent Literature 2: Japanese patent No. 4475084

### SUMMARY OF INVENTION

### Technical Problem

The transparent sealing material formed from a thermoplastic resin as described in Patent Literature 2 however has a problem that, in a combination of a base polymer and a softening agent, adhesive force is diminished to a sealing substrate or to a substrate forming an organic EL element. If the adhesive force to the substrates is low, there is a possibility that distortion or detachment of the substrate may occur due to the impact received in the production process or the like. Furthermore, external water vapor penetrates through the detached portion between the substrate and the sealing material, and causes the generation of dark spots. Therefore, the present invention addresses to the provision of a sealant composition which may have excellent filling properties and can exhibit excellent adhesive performance and holding force when produced into a sealing material, and a film or a sheet formed from the sealant composition.

### Solution to Problem

The above-described problems of the present invention have been solved by the following means.

(1) A sealant composition being adhesive for used in electronic devices, the sealant composition including an olefin-based polymer and a tackifier, wherein the olefin-based polymer is at least one selected from an ethylene/α-olefin copolymer and an ethylene/α-olefin/non-conjugated diene copolymer, and the content of the tackifier is 10% by mass or more and 70% by mass or less in the resin composition that constitutes the sealant composition.

(2) A sealant composition having adhesiveness for used in electronic devices, the sealant composition including an olefin-based polymer and a tackifier, wherein the olefin-based polymer is at least one selected from an ethylene/α-olefin copolymer and an ethylene/α-olefin/non-conjugated diene copolymer, and the content of the tackifier is 40% by mass or more and 70% by mass or less in the resin composition that constitutes the sealant composition.

(3) The sealant composition described in (1) or (2), wherein the tackifier is hydrogenated.

(4) The sealant composition described in any one of (1) to (3), wherein a hydrogenated tackifier is used as the tackifier which is a resin obtained by hydrogenating a petroleum resin containing a cyclic structure.

(5) The sealant composition described in any one of (1) to (4), wherein the ethylene/α-olefin copolymer and the ethylene/α-olefin/non-conjugated diene copolymer have a functional group selected from a carboxyl group, a hydroxyl group, an epoxy group, an amino group, an alkoxysilyl group, a sulfonic acid group, and a nitrile group.

(6) The sealant composition described in any one of (1) to (5), further including a softening agent.

(7) The sealant composition described in any one of (1) to (6), including:

(a) 10% to 35% by mass of the olefin-based polymer;

(b) 50% to 75% by mass of the tackifier; and

(c) 10% to 30% by mass of the softening agent,

relative to the total mass of the resin composition that constitutes the sealant composition.

(8) The sealant composition described in (7), wherein the softening agent is formed from a compound of which carbon number of the saturated hydrocarbon chain occupies 50% or more of the total carbon number.

(9) The sealant composition described in (8), wherein the compound of which carbon number of the saturated hydrocarbon chain occupies 50% or more of the total carbon number is a compound containing an isobutylene skeleton as a main component.

(10) The sealant composition described in any one of (1) to (9), wherein the number average molecular weight of the softening agent is 300 or more and 2000 or less.

(11) The sealant composition described in any one of (1) to (10), further including a desiccant.

(12) The sealant composition described in any one of (1) to (11), which is transparent in the visible region at 400 nm to 800 nm.

(13) A sealing film formed from the sealant composition described in any one of (1) to (12), or a sealing sheet having a peelable film laminated on one surface or on either surface of the sealing film.

(14) An organic light emitting device including a light emitting unit and the sealant composition described in any one of (1) to (13) on and/or around the light emitting unit, wherein the light emitting unit has a pair of electrode layers facing each other and an organic light emitting layer disposed between the electrode layers.

According to the present specification, the sealing film and the sealing sheet may be collectively referred to as sealing sheets.

Furthermore, according to the present specification, the “compound containing an isobutylene skeleton as a main component” refers to a compound in which the isobutylene component is 50% by mass or more, and preferably 80% by mass or more, relative to 100% by mass of the whole compound.

### Advantageous Effects of Invention

The sealant composition of the present invention can attain high adhesive force to a substrate that forms an organic EL element or a sealing substrate, and may have excellent interlayer filling properties and excellent holding force. Therefore, a sealing film formed using the composition can hardly cause distortion of the substrate under an impact during the process of forming an organic EL element, and the assembled organic EL element can attain high sealing performance and be excellent in view of preventing the occurrence of detachment and the penetration of moisture, so that the generation of dark spots in the organic EL element can be suppressed.

Other and further features and advantages of the invention will appear more fully from the following description, appropriately referring to the accompanying drawing.

### BRIEF DESCRIPTION OF THE DRAWING

FIG. 1 is a schematic cross-sectional diagram of an organic light emitting device 1 related to one embodiment of the present invention.

### MODE FOR CARRYING OUT THE INVENTION

### <Olefin-Based Polymer>

The olefin-based polymer used in the sealant composition of the present invention is an ethylene/α-olefin copolymer, or an ethylene/α-olefin/non-conjugated diene copolymer. Here, the α-olefin in the ethylene/α-olefin copolymer and the ethylene/α-olefin/non-conjugated diene copolymer is defined as an α-olefin excluding ethylene. Examples of this α-olefin include propylene, 1-butene, 1-pentene, 3-methyl-1-butene, 1-hexene, 3-methyl-1-pentene, 4-methyl-1-pentene, 3-ethyl-1-pentene, 1-octen, 1-decenen, and 1-undecene, and an α-olefin having 3 to 12 carbon atoms is preferred, while propylene and 1-butene are particularly preferred. The α-olefins listed above as examples can be used singly or in combination of two or more kinds. Examples of the ethylene/α-olefin copolymer include an ethylene/propylene copolymer, an ethylene/1-butene copolymer, an ethylene/1-pentene copolymer, an ethylene/3-methyl-1-butene copolymer, an ethylene/1-hexene copolymer, an ethylene/3-methyl-1-pentene copolymer, an ethylene/4-methyl-1-pentene copolymer, an ethylene/3-ethyl-1-pentene copolymer, an ethylene/1-octene copolymer, an ethylene/1-decene copolymer, and an ethylene/1-undecene copolymer. Among them, an ethylene/propylene copolymer and an ethylene/1-butene copolymer are preferable. The ethylene/α-olefin copolymers listed above as examples can be used singly or in combination of two or more kinds.

The amount of incorporation of the olefin-based polymer is preferably 10% to 90% by mass, and more preferably 10% to 80% by mass, relative to the total mass of the sealant composition. Also, in a case in which the sealant composition contains a softening agent, the amount of incorporation of the olefin-based polymer is preferably 10% to 35% by mass relative to the total mass of the sealant composition.

Furthermore, examples of the non-conjugated diene in the case of using an ethylene/α-olefin/non-conjugated diene copolymer include 1,4-pentadiene, 1,4-hexadiene, 1,5-hexadiene, 1,7-octadiene, 1,9-decadiene, 3,6-dimethyl-1,7-octadiene, 4,5-dimethyl-1,7-octadiene, 5-methyl-1,8-nonadiene, dicyclopentadiene, 5-ethylidene-2-norbornene, 5-vinyl-2-norbornene, and 2,5-norbornadiene. These can be used singly or in combination of two or more kinds.

Examples of the ethylene/α-olefin/non-conjugated diene copolymer include an ethylene/propylene/dicyclopentadiene copolymer, an ethylene/propylene/5-ethylidene-2-norbornene copolymer, an ethylene/1-butene/dicyclopentadiene copolymer, and an ethylene/1-butene/5-ethylidene-2-norbornene copolymer. These can be used singly or in combination of two or more kinds.

The ethylene/α-olefin copolymer and the ethylene/α-olefin/non-conjugated diene copolymer may be a polymer containing a constituent unit derived from another monomer (i) among various polymers. Regarding the other monomer (i), an unsaturated compound having a functional group such as a carboxyl group, a hydroxyl group, an epoxy group, an amino group, an alkoxysilyl group, a sulfonic acid group, or a nitrile group is preferred. Such unsaturated compound can be used singly or in combination of two or more kinds. Furthermore, the amount of use of the unsaturated compound is preferably 0.01% to 10% by mass, and more preferably 0.1% to 5% by mass, relative to the total amount of the monomers used in polymerization.

Regarding the unsaturated compound having a carboxyl group, maleic anhydride, (meth)acrylic acid, a cyclic compound represented by the following formula (1), and the like can be used.

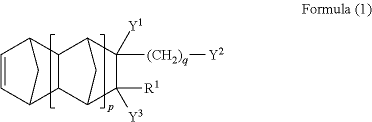

(In formula (1), R¹ represents a hydrogen atom or a hydrocarbon group having 1 to 10 carbon atoms; Y¹, Y² and Y³ each independently represent a hydrogen atom, a hydrocarbon group having 1 to 10 carbon atoms, or —COOH; at least one among Y¹, Y² and Y³ represents —COOH; and when two or more of Y¹, Y² and Y³ represent —COOH, those may be linked together and form an acid anhydride (—CO—(O)—CO—). P is an integer of 0 to 2; and q is an Integer of 0 to 5.)

Examples of the cyclic compound represented by Formula (1) include 5,6-dimethyl-5,6-dicarboxy-bicyclo[2.2.1]-2-heptene, 5,6-diethyl-5,6-dicarboxy-bicyclo[2.2.1]-2-heptene, 5,6-dimethyl-5,6-bis(carboxymethyl)-bicyclo[2.2.1]-2-heptene, 5,6-diethyl-5,6-bis(carboxymethyl)-bicyclo[2.2.1]-2-heptene, 5-methyl-5-carboxy-bicyclo[2.2.1]-2-heptene, 5-ethyl-5-carboxy-bicyclo[2.2.1]-2-heptene, 5-carboxy-5-carboxymethyl-bicyclo[2.2.1]-2-heptene, 5-methyl-5-carboxymethyl-bicyclo[2.2.1]-2-heptene, 5-ethyl-5-carboxymethyl-bicyclo[2.2.1]-2-heptene, 8,9-dimethyl-8,9-dicarboxy-tetracyclo[4.4.0.12,5.17,10]-3-dodecene, 8,9-diethyl-8,9-dicarboxy-tetracyclo[4.4.0.12,5.17,10]-3-dodecene, 8-methyl-8-carboxy-tetracyclo[4.4.0.12,5.17,10]-3-dodecene, and 8-ethyl-8-carboxy-tetracyclo[4.4.0.12,5.17,10]-3-dodecene. These can be used singly or in combination of two or more kinds.

The amount of use in the case of using the cyclic compound represented by formula (1) is preferably 0.01% to 15% by mass, and more preferably 0.1% to 10% by mass, relative to the total amount of the monomers.

The ethylene/α-olefin copolymer or ethylene/α-olefin/non-conjugated diene copolymer obtained by copolymerizing the cyclic compound represented by formula (1) is preferably a random copolymer. Furthermore, the mass average molecular weight Mw of the random copolymer obtained by copolymerization, which is calculated by GPC relative to polystyrene standards, is preferably 1,000 to 3,000,000, more preferably 3,000 to 1,000,000, and further preferably 5,000 to 700,000.

Regarding the olefin-based polymer related to the present invention, the ethylene/α-olefin copolymers and ethylene/α-olefin/non-conjugated diene copolymers listed above as examples can be used singly or in combination of two or more kinds.

Preferred is an ethylene/α-olefin/non-conjugated diene copolymer, and more preferred is an ethylene/propylene/dicyclopentadiene copolymer. Furthermore, when an ethylene/1-butene/5-ethylidene-2-norbornene copolymer or an ethylene/propylene/5-ethylidene-2-norbornene copolymer is used, a sealing material having particularly excellent heat resistance, insulating properties and lightweightness can be obtained, and even more complicated requirement characteristics as in the case of organic EL devices for vehicle mounting can be coped therewith, which is preferable.

### <Tackifier>

According to the present invention, when a tackifier is added to the olefin-based polymer, not only the viscosity can be decreased, but also adhesiveness can be imparted, and the wettability and adhesive force of the sealing material (sealing film) can be enhanced.

Examples of the tackifier include rosin, rosin derivatives (hydrogenated rosin, heterogenized rosin, polymerized rosin, rosin esters (esterified rosins of alcohol, glycerin, pentaerythritol, and the like), hydrogenated rosin esters), terpene resins (α-pinene and β-pinene), terpene derivatives (terpene phenol resins, aromatic modified terpene resins, hydrogenated terpene resins, and hydrogenated terpene phenol resins), aliphatic petroleum resins, aromatic petroleum resins, copolymer-based petroleum resins, alicyclic petroleum resins, coumarone-indene resins, phenolic resins, and xylene resins.

Among them, one or more selected from the group consisting of hydrogenated petroleum resins, hydrogenated rosin-based resins, and hydrogenated terpene-based resins can preferably be used from the viewpoint of having satisfactory compatibility with the olefin-based polymers, and being capable of forming a sealing material having excellent transparency. Examples of such a hydrogenated petroleum resin include hydrogenated dicyclopentadiene-based resins, which are C5-based hydrogenated petroleum resins obtained by copolymerizing the C5 fraction components such as pentene, isoprene, piperine, and 1,3-pentadiene produced by thermal cracking of petroleum naphtha (manufactured by Tonex Co., Ltd.: ESCOLET 5300 and 5400 series, manufactured by Eastman Chemical Co.: EASTOTAC H series, and the like), partially hydrogenated aromatic modified dicyclopentadiene-based resins (manufactured by Tonex Co., Ltd.: ESCOLET 5600 series, and the like), C9-based hydrogenated petroleum resins obtainable by copolymerizing the C9 fraction components such as indene, vinyltoluene, and α- or β-methylstyrene produced by thermal cracking of petroleum naphtha (manufactured by Arakawa Chemical Industries, Ltd.: ARKON P or M series), and C5/C9-based copolymer-based hydrogenated petroleum resins of the C5 fraction components and the C9 fraction components described above (manufactured by Idemitsu Kosan Co., Ltd.: I-MARV series). Among these, a resin obtained by hydrogenated a petroleum resin containing a cyclic structure, particularly a resin obtained by hydrogenating a petroleum resin containing a dicyclopentadiene structure, can preferably be used from the viewpoint of having satisfactory compatibility with the olefin-based polymers.

The amount of incorporation of the tackifier is 10% to 70% by mass relative to the total mass of the sealant composition, and preferably, the tackifier may be incorporated in an amount in the range of 40% to 70% by mass. Furthermore, when the sealant composition contains a softening agent, the amount of incorporation of the tackifier is preferably 50% to 70% by mass relative to the total mass of the sealant composition. If the amount of incorporation is less than 10% by mass, the tacky power can be insufficient, and the adhesive force cannot be increased. If the amount of incorporation is more than 70% by mass, flexibility can be insufficient because the effect of the softening agent on lowering the viscosity can be disturbed.

### <Additives>

The sealing material of the present invention may contain optional additives in addition to the olefin-based polymer and the tackifier, to the extent that the effects of the present invention and transparency are not impaired. Examples of such additives include a softening agent, a desiccant, a filler, an ultraviolet absorber, an ultraviolet stabilizer, an oxidation inhibitor, and a resin stabilizer. These additives are further explained below.

### (Softening Agent)

Examples of the softening agent include fatty oil-based agents such as stearic acid, castor oil, and palm oil; rosin-based agents such as rosin and pine tar; petroleum-based agents such as saturated olefin aromatic materials (mineral oil, naphthenic oil, and the like), unsaturated olefin aromatic materials (naphthalene oil and the like), paraffin, paraffin chloride, coal tar-based agents such as tar, synthetic resin-based low polymerization phenol formaldehyde resins, low melting point styrene resins, low molecular weight polyisobutylene, polybutene, and tert-butylphenol acetylene condensate.

Among them, one or more selected from the group consisting of naphthenic oil, paraffin, and saturated synthetic resin-based softening agents, in which the number of carbon atoms of the saturated hydrocarbon chain occupies 50% or more of the total number of carbon atoms, can preferably be used from the viewpoint of being capable of forming a sealing material having excellent weather resistance. Particularly, examples of the saturated synthetic resin-based softening agents include low molecular weight polyisobutylenes having a degree of polymerization of about 10 to several hundreds, which are produced by polymerizing isobutylene alone or a C4 gas including this in the presence of a Lewis acid catalyst (manufactured by BASF SE; GLISSOPAL series, and the like), polybutenes having a molecular structure of a long-chain hydrocarbon obtainable by cationically polymerizing isobutene as a main component with a portion of normal-butene (manufactured by JX Nippon Oil & Energy Corp.: NISSEKI POLYBUTENE series, manufactured by NOF Corp.: EMULWET series, and the like), resins obtained by hydrogenating polybutene (manufactured by NOF Corp.: PARLEAM series), and resins obtained by hydrogenating isoprene (manufactured by Kuraray Co., Ltd.: LIR200 series). Among these, polybutene having an isobutylene skeleton can preferably be used from the viewpoint of having a high effect of decreasing the viscosity and having satisfactory water vapor barrier properties.

Furthermore, regarding the number average molecular weight of the softening agent, a softening agent having a value of 300 or more and 2000 or less is preferably used. If the number average molecular weight of the softening agent is too small, the softening agent may migrate to the organic EL element, and dark spots can be generated, which lead to deterioration of visibility. If the number average molecular weight of the softening agent is too large, the effect of decreasing the viscosity is small, and it cannot be effective.

The amount of incorporation of the softening agent is preferably 10% to 30% by mass relative to the total mass of the sealant composition.

### (Desiccant)

The sealing material of the present invention preferably contains a desiccant for the purpose of capturing moisture that penetrates through the sealant composition. By capturing moisture, deterioration of the organic EL element by moisture can be suppressed.

The desiccant may any one of a metal oxide desiccant or an organic desiccant, and there are no particular limitations. For example powdered inorganic oxides such as barium oxide (BaO), calcium oxide (CaO), strontium oxide (SrO), and magnesium oxide (MgO); and organic compounds known as transparent moisture getter agents can be used. Furthermore, these moisture capturing agents can be used singly or as mixtures of two or more kinds.

A metal oxide-based desiccant is usually added in the form of powder. It may usually be acceptable if the average particle size thereof is in the range of less than 20 μm, and the average particle size is preferably 10 μm or less, and more preferably 1 μm or less. As will be described below, in a case in which the sealant composition is produced into a film, the metal oxide-based desiccant should be sufficiently made smaller than the film thickness. When the particle size is adjusted as such, the possibility of effecting damage to the organic EL element is lowered, and the desiccant particles can be prevented from interrupting image recognition. However, if the average particle size is less than 0.01 μm, the production cost may be increased in order to prevent scattering of the desiccant particles. Therefore, the lower limit of the particle size may appropriately be adjusted in consideration of this point.

The organic compound as a moisture getter agent may be any material that takes in water by a chemical reaction, and does not turn opaque before and after the reaction. Particularly, the organometallic compound is preferable due to the drying ability. The organometallic compound according to the present invention means a compound having a metal-carbon bond, a metal-oxygen bond, a metal-nitrogen bond, or the like. When water and the organometallic compound react with each other, the bonds described above are broken by a hydrolysis reaction, and the compound is converted to a metal hydroxide. Depending on the metal, the metal hydroxide may be subjected to hydrolysis polycondensation after the reaction into a high molecular weight compound.

Preferred examples of the organometallic compound include metal alkoxides, metal carboxylates, and metal chelates.

Regarding the metal, it is desirable to use a metal atom which is highly reactive with water as an organometallic compound, that is, a metal atom which is easily breakable from various bonds under the effect of water. Specific examples thereof include aluminum, silicon, titanium, zirconium, silicon, bismuth, strontium, calcium, copper, sodium, and lithium. Further examples include cesium, magnesium, barium, vanadium, niobium, chromium, tantalum, tungsten, chromium, indium, and iron. Particularly, a desiccant of an organometallic compound having aluminum as the center metal can be preferable from the viewpoints of dispersibility in a resin and reactivity with water.

Examples of the organic group include a alkoxy group, a carboxyl group, a β-diketonate group such as an acetylacetonate group, or a dipivaloylmethanate group, containing an unsaturated hydrocarbon, a saturated hydrocarbon, a branched unsaturated hydrocarbon, a branched saturated hydrocarbon, or a cyclic hydrocarbon, such as a methoxy group, an ethoxy group, a propoxy group, a butoxy group, a 2-ethylhexyl group, an octyl group, a decyl group, a hexyl group, an octadecyl group, or a stearyl group.

Among compounds represented by the following formula (2), an aluminum ethylacetoacetate compound having 1 to 8 carbon atoms can preferably be used from the viewpoint that a sealant composition having excellent transparency can be formed.

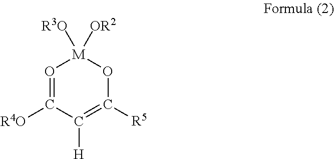

(In the formula, R² to R⁵ represent an organic group containing an alkyl group, an aryl group, an alkoxy group, a cycloalkyl group, or an acyl group; M represents a trivalent metal atom (preferably, among the metals listed as the metal of the organic metal compounds described above, a metal having trivalency). Here, R² to R⁵ may be the same organic groups, or may be different organic groups.)

As to the organic group represented by R² to R⁵, if the number of carbon atoms is small, the organic group can bring about excellent compatibility with the olefin-based polymer of constituting the base polymer. Besides, if the number of carbon atoms is large, the organic group can bring about favorable stability of the product after hydrolysis, while the organic EL element cannot be easily deteriorated thereby. Therefore, when transparency is secured, and the balance described above is considered, the organic group is preferably an organic group in which R² and R³ represent an organic group having 1 to 8 carbon atoms, and the sum of the numbers of carbon atoms of R⁴ and R⁵ is 5 or less.

The aluminum ethyl acetoacetate compound in which the number of carbon atoms for R² to R⁵ in formula (2) above is 1 to 8 is marketed and available from, for example, Kawaken Fine Chemicals Co., Ltd., and Hope Chemical Co., Ltd.

The amount of addition of the desiccant is preferably 0.05 to 10 parts by mass, and more preferably 1 to 5 parts by mass, relative to 100 parts by mass of the sealant composition. If the amount of addition of the desiccant material is too large, the desiccant not only captures the moisture that penetrates through the sealant composition, but also actively absorbs moisture. Therefore, there is a decrease in the water vapor barrier properties.

### (Filler, Ultraviolet Absorber, Ultraviolet Stabilizer and the Like)

Furthermore, examples of the filler include calcium carbonates or magnesium carbonates, such as calcium carbonate, magnesium carbonate, and dromite; silicates such as kaolin, calcined clay, pyrophyllite, bentonite, sericite, zeolite, talc, attapulgite, and wollastonite; silicic acid such as diatomaceous earth and silica powder; aluminum hydroxide; pearlite; barium sulfate such as precipitated barium sulfate; calcium sulfate such as gypsum; calcium sulfite; carbon black, zinc oxide, and titanium dioxide.

These fillers are such that for example, when the decrease in transparency of the sealing material caused by light scattering is considered, the average primary particle size of the filler is preferably 1 to 100 nm, and more preferably 5 to 50 nm. Also, in the case of using a plate-shaped or scale-shaped filler in order to further increase low moisture permeability, the average primary particle size is preferably 0.1 to 5 μm. Furthermore, from the viewpoint of dispersibility in a resin, a filler obtained by hydrophobizing the surface of a hydrophilic filler is preferably used. Examples of the hydrophobic filler include fillers obtained by treating the surface of conventional hydrophilic fillers using alkyl, aryl or aralkyl-based silane coupling agents having hydrophobic groups, such as n-octyltrialkoxysilane; silylating agents such as dimethyldichlorosilane and hexamethyldisilazane; polydimethylsiloxanes having hydroxyl groups at the ends; higher alcohols such as stearyl alcohol; and higher fatty acids such as stearic acid.

The filler may be used singly, or two or more kinds may be used in mixture. The amount of addition of the filler, if added, can be in the range of 0.01% to 20% by mass relative to the total amount of the sealant composition or the sealant material.

Examples of the ultraviolet absorber include benzotriazole-based compounds, oxazolic acid amide-based compounds, and benzophenone-based compounds. The amount of addition of the ultraviolet absorber, if added, can be in the range of about 0.01% to 3% by mass relative to the total amount of the sealant composition or the sealant material.

Examples of the ultraviolet stabilizer include hindered amine-based compounds. The amount of addition of the ultraviolet stabilizer, if added, can normally be in the range of about 0.01% to 3% by mass relative to the total amount of the sealant composition or the sealant material.

Examples of the oxidation inhibitor include hindered phenol-based compounds and phosphoric acid ester-based compounds. The amount of addition of the oxidation inhibitor, if added, can normally be in the range of about 0.01% to 2% by mass relative to the total amount of the sealant composition or the sealant material.

Example of the resin stabilizer include phenolic resin stabilizers, hindered amine-based resin stabilizers, imidazole-based resin stabilizers, dithiocarbamic acid salt-based resin stabilizers, phosphorus-based resin stabilizers, and sulfur ester-based resin stabilziers. <Moisture Permeability>

The sealant composition of the present invention preferably has a moisture permeability at 40° C. and 90% RH (relative humidity) of 50 g/m²·day or less, as measured by the test method described below.

More preferably, the moisture permeability is 20 g/m²·day or less, and particularly preferably 15 g/m²·day or less. The lower limit value is not particularly limited, and as the value is lower, moisture penetration from the outside can be prevented. In the case of a sealing material based on a resin, the moisture permeability may be considered to be about 1 g/m²·day. When the moisture permeability is 50 g/m²·day or less, moisture penetration from the outside can be prevented, and dark spots of the organic EL element can be suppressed. On the other hand, if the moisture permeability is too high, moisture penetration cannot be prevented, and dark spots of the organic EL element may eventually be induced. Generally, a resin having higher saturation has superior moisture permeability. Thus, in the present invention, when the amount of addition of the tackifier is increased, or when the tackifier is hydrophobized, the moisture permeability can be increased.

### <Adhesive Force>

The sealant composition of the present invention preferably has an adhesive force of 10 N/25 mm or more as measured by the test method described below. The adhesive force is more preferably 20 N/25 mm or more, and particularly preferably 30 N/25 mm or more. When the sealant composition has an adhesive force of 10 N/25 mm or more, since the sealant composition is not detached from the substrate or the sealing plate, moisture penetration through the interface can be prevented. On the other hand, if the adhesive force is too small, the substrate may be distorted, or the sealant composition is detached from the substrate or the sealing substrate, and moisture penetration through the interface cannot be prevented. Thus, dark spots of the organic EL element can consequently be induced. The adhesive force is affected by the tacky power, fluidity and cohesive force. The tacky power is enhanced by increasing the amount of addition of the tackifier, fluidity is enhanced by increasing the amount of addition of the softening agent, and the cohesive force is enhanced by increasing the amount of addition of the olefin-based polymer. Therefore, the adhesive force can be controlled by adjusting the mixing ratio of the various ingredients.

The sealant composition of the present invention can be used on and/or around a light emitting unit of an organic light emitting device (organic EL element), to form a portion of the organic EL element. Furthermore, the sealant composition of the present invention can be shaped into a film or a sheet, and an organic light emitting device can be assembled using this film or sheet. The method is described in the following.

### <Sealing Film>

It is preferable that the sealant composition of the present invention is formed as a sealing film on a protective film by a conventionally known method and supplied as a sealing sheet. The protective film may be a peelable film that has been subjected to an easy peeling treatment with silicone or the like, or may be a general polyethylene terephthalate (PET) film or an oriented polypropylene (OPP) film.

The thickness of the sealing film is not particularly limited, and can be appropriately selected according to the use. Usually, the thickness is 10 to 100 μm, and preferably 10 to 40 μm. If the sealing film is too thin, since the adhesive force to a substrate or a sealing substrate is insufficient, moisture may penetrate through the interface. If the sealing film is too thick, the end surface of the sealing film that is exposed to air after sealing is enlarged, and the amount of water absorption through the end surface is hence increased. The water vapor barrier properties are consequently decreased.

The method for forming a sealing film is not particularly limited, and a conventionally known method can be used. For example, a coating liquid for forming a sealing film is obtained by dissolving and dispersing the sealant composition in an organic solvent. Next, the coating liquid is applied over the entire surface of the peeling treated surface of a peelable protective film using an applicator or the like, and thus a sealing film is formed. Thereafter, the sealing film is dried, and the peelable protective film (peeling film) is laminated thereon. Thereby, a sealing sheet can be formed. The organic solvent is not particularly limited, but for example, toluene, methyl ethyl ketone (MEK), ethyl acetate, dimethylacetamide, N-methyl-2-pyrrolidone, and mixed solutions thereof can preferably be used. The method for applying the coating liquid on a peelable protective film layer is not particularly limited, and a conventionally known method can be used. Examples thereof include a roll coating method, a gravure coating method, a reverse coating method, a spray coating method, an air knife coating method, a curtain coating method, a die coating method, and a comma coating method.

Various embodiments can be considered for the supplied form of the sealing sheet that is produced as described above. For example, an embodiment of peelable film/sealing film/peelable film may be employed, or an embodiment of gas barrier film or glass/sealing film/peelable film is acceptable. Incidentally, in order to maintain the sealing performance of the sealing film, it is preferable to seal and store this together with a desiccant such as silica gel, calcium oxide, or calcium chloride. Specifically, deterioration of an organic light emitting device sealed with a sealing film can be delayed by maintaining the moisture content according to the Karl-Fischer method of the sealing film to be 0 to 0.2% by mass.

### <Sealing Sheet>

The sealing sheet of the present invention is, for example, a product in which a peelable film is laminated on one surface or either surface of a sealing film constituted of a sealant composition that has been formed into a film, as explained above. An embodiment can be included in which the peelable film is laminated on only one surface, and besides a gas barrier film, a glass plate, a metal plate, foil, or the like is pasted on the opposite surface of the peelable film.

Such an embodiment can be obtained by, for example, overlapping a sealing sheet having a peelable film laminated on only one surface, to be in contact with a sealing film, a gas barrier film, a glass plate, a metal plate, foil, or the like, and compressing the assembly.

### <Organic Light Emitting Device>

Since the sealing film using the sealant composition of the present invention has both high water vapor barrier properties and adhesiveness, the water vapor permeability through the sealing end surface can be suppressed to a low level. Thus, the sealing film can be applied to the sealing of a display or a lighting device without further sealing the periphery of an organic light emitting unit with glass frit or the like.

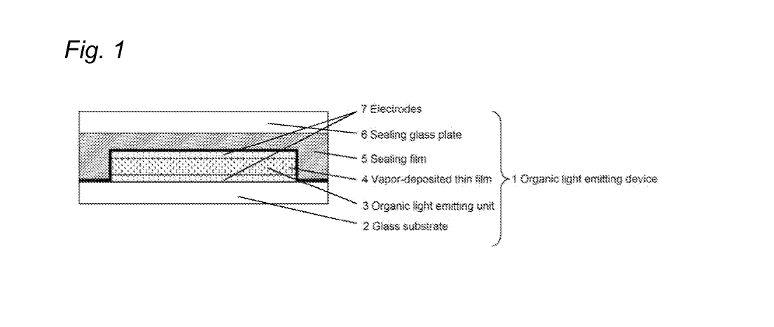

FIG. 1 is a schematic cross-sectional diagram of an organic light emitting device 1 related to one embodiment of the present invention. This organic light emitting device 1 is configured to include an organic light emitting unit 3 formed on a glass substrate 2, a sealing film 5 disposed on top and in the periphery of this organic light emitting unit 3, and a sealing glass plate 6.

The organic light emitting unit 3 is formed so as to be disposed between a pair of electrodes 7 on the glass substrate 2. After this organic light emitting unit 3 and the electrodes 7 are formed, if organic and inorganic thin films having gas barrier properties are formed to cover the organic light emitting unit and the electrodes, it is more effective in preventing deterioration of the organic light emitting device, synergistically collaborating with the effect of the sealing film 5.

In this organic light emitting device 1, the sealing end surface is exposed, and thus the organic light emitting device is not subjected to a sealing treatment using glass frit or the like.

As such, since the composition for sealing of the present invention has both high water vapor barrier properties and adhesiveness, when the composition is applied to a display or a lighting device, the structure of the device can be simplified, and the cost can be reduced.

### EXAMPLES

The present invention will be described in more detail based on examples given below, but the invention is not meant to be limited by these.

### Example 1

40 parts by mass of an ethylene/propylene/5-ethylidene-2-norbornene copolymer (EPDM) (manufactured by Mitsui Chemicals, Inc., “MITSUI EPT X-3012P”, ethylene content: 73% by mass, propylene content: 23% by mass, 5-ethylidene-2-norbornene content: 4% by mass, water vapor permeability: 0.6 g·mm/m²·day) was dissolved and stirred in MEK such that the concentration of the copolymer was adjusted to a solid content of 20% by mass. Subsequently, 60 parts by mass of ESCOLET 5600 (manufactured by Tonex Co., Ltd.: partially hydrogenated aromatic modified dicyclopentadiene-based resin) as a tackifier was added thereto, and MEK was further incorporated therein and stirred to obtain a solid content of 30% by mass until a uniform state was obtained. Thus, resin mixed solution was obtained.

On a peelable surface of a peeling-treated polyester film (manufactured by DuPont Teijin Films, Ltd., PUREX A-314) having a thickness of 50 μm as a base material sheet, the resin mixed solution obtained as described above was applied to be a thickness of 50 μm, and was heated and dried at 130° C. for 3 minutes. Thus, a sealing layer was formed. A peeling-treated polyester film (manufactured by Toyobo Co., Ltd., TOYOBO ESTER FILM E7006) having a thickness of 25 μm as a release film was laminated on the surface of the dried sealing layer such that the peelable surface was brought into contact with the sealing layer. Thus, a transparent resin sheet for organic EL element sealing (sealing sheet) related to Example 1 having a uniform thickness was produced.

### Examples 2 to 11

Transparent resin sheets for organic EL element sealing related to Examples 2 to 11 were produced in the same manner as in Example 1, except that the mixing compositions indicated in Table 1 were used.

### Comparative Examples 1 to 5

Transparent resin sheets for organic EL element sealing related to Comparative Examples 1 to 5 were produced in the same manner as in Example 1, except that the mixing compositions indicated in Table 2 were used.

### (Raw Materials)

### <Olefin-Based Polymer>

A1: Ethylene/propylene/5-ethylidene-2-norbornene copolymer (manufactured by Mitsui Chemicals, Inc., EPT X-3012P, ethylene content: 73% by mass, propylene content: 23% by mass, and 5-ethylidene-2-norbornene content: 4% by mass)
A2: Ethylene/propylene/dicyclopentadiene copolymer (manufactured by Mitsui Chemicals, Inc., EPT1070, ethylene content: 57%, propylene content: 39%, and dicyclopentadiene content: 4% by mass)
A3: Ethylene/butene copolymer (manufactured by Mitsui Chemicals, Inc., TAFMER A4085)

### <Tackifier>

B1: ESCOLET 5600 (manufactured by Tonex Co., Ltd.: partially hydrogenated aromatic modified dicyclopentadiene-based resin)
B2: IMARV P100 (manufactured by Idemitsu Kosan Co.,Ltd.: C5/C9-based hydrogenated petroleum resin)
B3: PINECRYSTAL KE311 (manufactured by ARAKAWA CHEMICAL INDUSTRIES, LTD.: Hydrogenated rosin ester)
B4: CLEARON P-115 (manufactured by YASUHARA CHEMICAL CO., LTD.: Hydrogenated terpene)
B5: ESCOLET 1310 (manufactured by Tonex Co., Ltd.: C5-based petroleum resin)

### <Softening Agent>

C1: NISSAN POLYBUTENE 200N (manufactured by NOF Corp.: polybutene (isobutylene component: 98% by mass or more), number average molecular weight 2650)
C2: NISSAN POLYBUTENE ON (manufactured by NOF Corp.: polybutene (isobutylene component: 98% by mass or more), number average molecular weight 370)

### <Desiccant>

D1: Aluminum trisethylacetoacetate ALCH-TR (manufactured by Kawaken Fine Chemicals Co., Ltd.: compound represented by the following chemical formula, molecular weight: 414)

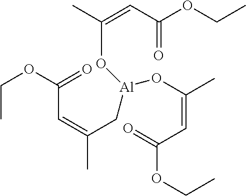

### (Test Methods)

Evaluation was performed according to the following test methods. The results are shown in Tables 1 and 2.

### <Light Transmittances>

The light transmittances of the transparent resin compositions for organic EL element sealing were determined using a spectrophotometer (spectrophotometer Model U-4100 manufactured by Hitachi High-Technologies Corp., solid sample analyzing system). Specifically, a transparent resin sheet for organic EL element sealing was produced by pasting each of the sheets to a thickness of 0.1 mm at 80° C., and the amount of transmitted light at 550 nm at 25° C. was determined.

### <Moisture Permeability>

The 25-μm peeling-treated polyester film and the 50-μm peeling-treated polyester film of the transparent resin sheet for organic EL element sealing thus produced were peeled off, and the transparent resin sheet was mounted between a low humidity chamber and a high humidity chamber such that any wrinkles or sagging was not observed. The moisture permeability at 40° C. and 90% RH was determined according to JIS K7129C using a differential pressure type gas/vapor permeability analyzer (manufactured by GTR Tec Corp., GTR-10XAWT) and a gas chromatography system (manufactured by Yanaco Group, G2700T).

### <Adhesive Force>

The 25-μm peeling-treated polyester film of the transparent resin sheet for organic EL element sealing thus produced was peeled off, and a 38-μm easy adhesion-treated polyester film (manufactured by DuPont Teijin Films Corp., G2-C) was pasted thereon at 80° C. Subsequently, the 50-μm peeling-treated polyester film was peeled off, and thus a specimen was obtained. On the surface of the sealing layer of the specimen thus obtained, a glass plate according to JIS R3202 was bonded as an adherend at a bonding temperature of 80° C., and the specimen was peeled off from the adherend by the 180° C. peeling method according to JIS Z0237. Thus, the adhesive force was evaluated.

### <Holding Force>

A specimen was produced in the same manner as in the case of the evaluation of adhesive force, and on the surface of the sealing layer of the specimen thus obtained, a glass plate according to JIS R3202 was bonded as an adherend at a bonding temperature of 80° C., and a weight defined according to JIS Z0237 was suspended therefrom. Thus, the distance of shift made after the passage of 24 hours at 100° C. was evaluated as the holding force. Incidentally, when the specimen was peeled off within 24 hours was designated as “>25”.

### <Dark Spots>

On an element substrate formed from insulating transparent glass, an organic EL element was produced, provided with a positive electrode, organic layers on the top surface thereof, and a negative electrode on the top surface thereof. Subsequently, the 25-μm peeling-treated polyester film of the transparent resin sheet for organic EL element sealing thus produced was peeled off, and the polyester film was disposed on the top surface of the negative electrode of the organic EL element. Thereafter, the 50-μm peeling-treated polyester film of the transparent resin sheet for organic EL element sealing was peeled off, and an insulating transparent glass plate as a sealing substrate was disposed on the top surface of the sealing layer of the transparent resin sheet for organic EL element sealing. The assembly was pressed for 1 minute under reduced pressure, at a pressure of 0.6 MPa at 80° C. Thus, a model of an organic EL display was produced.

Next, the model was treated for 500 hours at 80° C. and 85% RH, and subsequently the model was cooled to room temperature (25° C.). Then, the organic EL element was driven, and dark spots (non-light emitting sites) were observed. The case in which the area of dark spots was less than 2% relative to the entire area was rated as “AA” for being especially excellent in suppressing the generation of dark spots; the case in which the area of dark spots was less than 5% was rated as “A” for being excellent in suppressing the generation of dark spots; the case in which the area of dark spots was less than 10% was rated as “B” for being excellent in suppressing the generation of dark spots; and the case in which the area of dark spots was 10% or more was rated as “C” for being inferior in suppressing the generation of dark spots.

TABLE 1

| | Ex 1 | Ex 2 | Ex 3 | Ex 4 | Ex 5 | Ex 6 | Ex 7 | |
|---|---|---|---|---|---|---|---|---|
| Olefin-based polymer A1 | 40 | | | 40 | | 40 | 40 | |
| Olefin-based polymer A2 | | 40 | | | | | | |
| Olefin-based polymer A3 | | | 40 | | 40 | | | |
| Tackifier B1 | 60 | 60 | 60 | | | | | |
| Tackifier B2 | | | | 60 | | | | |
| Tackifier B3 | | | | | 60 | | | |
| Tackifier B4 | | | | | | 60 | | |
| Tackifier B5 | | | | | | | 60 | |
| Softening agent C1 | | | | | | | | |
| Softening agent C2 | | | | | | | | |
| Desiccant D1 | | | | | | | | |
| Light transmittance [%] | 92 | 92 | 91 | 92 | 90 | 90 | 86 | |
| Moisture permeability 40° C. 90% | 7.7 | 9.8 | 11.6 | 8.2 | 18.7 | 18.2 | 20.7 | |
| [g/m² · day] | | | | | | | | |
| Adhesive force to glass [N/25 mm] | 32.7 | 33.0 | 35.8 | 27.3 | 332 | 30.2 | 28.4 | |
| Holding force [mm] | 4.5 | 4.5 | 4.0 | 5.0 | 4.5 | 4.5 | 4.5 | |
| Dark spot | AA | AA | AA | AA | AA | AA | A | |
| | Ex 8 | Ex 9 | Ex 10 | Ex 11 | Ex 12 | Ex 13 | Ex 14 | Ex 15 |
| Olefin-based polymer A1 | 20 | 50 | 55 | 60 | 80 | 20 | 20 | 20 |
| Olefin-based polymer A2 | 20 | | | | | | | |
| Olefin-based polymer A3 | | | | | | | | |
| Tackifier B1 | 60 | 50 | 45 | 40 | 20 | 70 | 70 | 65 |
| Tackifier B2 | | | | | | | | |
| Tackifier B3 | | | | | | | | |
| Tackifier B4 | | | | | | | | |
| Tackifier B5 | | | | | | | | |
| Softening agent C1 | | | | | | 10 | | |
| Softening agent C2 | | | | | | | 10 | 10 |
| Desiccant D1 | | | | | | | | 5 |
| Light transmittance [%] | 90 | 92 | 92 | 91 | 90 | 92 | 92 | 89 |
| Moisture permeability 40° C. 90% | 13.4 | 14.0 | 14.4 | 21.9 | 7.5 | 8.4 | 7.1 | |
| [g/m² · day] | | | | | | | | |
| Adhesive force to glass [N/25 mm] | 34.7 | 24.8 | 23.3 | 21.7 | 14.2 | 40.5 | 36.5 | 34.1 |
| Holding force [mm] | 4.5 | 5.0 | 5.0 | 5.5 | 6.5 | 4.0 | 4.0 | 4.5 |
| Dark spot | AA | AA | AA | AA | B | AA | AA | AA |

″Ex″ means Example.

| | C Ex1 | C Ex 2 | C Ex 3 | C Ex 4 | C Ex 5 | C Ex 6 | C Ex 7 |
|---|---|---|---|---|---|---|---|
| Olefin-based polymer A1 | 65 | 60 | 95 | 40 | 40 | 25 | 20 |
| Olefin-based polymer A2 | | | | | | | |
| Olefin-based polymer A3 | | | | | | | |
| Tackifier B1 | 5 | | | | | 75 | 75 |
| Tackifier B2 | | | | | | | |
| Tackifier B3 | | | | | | | |
| Tackifier B4 | | | | | | | |
| Tackifier B5 | | | | | | | |
| Softening agent C1 | 30 | | | 60 | | | 5 |
| Softening agent C2 | | 40 | | | 60 | | |
| Desiccant D1 | | | 5 | | | | |
| Light transmittance [%] | 91 | 90 | 91 | 90 | 91 | 91 | 90 |
| Moisture permeability 40° C. 90% | 90.8 | 185.7 | 67.5 | — | — | 7.2 | 7.4 |
| [g/m² · day] | | | | | | | |
| Adhesive force to glass [N/25 mm] | 9.5 | 8.0 | 2.2 | 0.6 | 0.5 | — | — |
| Holding force [mm] | >25 | >25 | >25 | >25 | >25 | — | — |
| Dark spot | C | C | C | C | C | — | — |

(Remarks) ″—″ indicates that testing could not be carried out.
″C Ex″ means Comparative Example.

In Examples 1 to 6, 8 to 11, and 13 to 15, an ethylene/α-olefin copolymer or an ethylene/α-olefin/non-conjugated diene copolymer, and 40% by mass or more and 70% by mass or less of a hydrogenated tackifier were contained, and thus a moisture permeability at 40° C. and 90% RH of 20 g/m²·day or less and an adhesive force of 20 N/25 mm or more were exhibited. Also, particularly satisfactory results were obtained in the evaluation of dark spots.

In Example 7, 40% by mass of an ethylene/α-olefin/non-conjugated diene copolymer and 60% by mass of a tackifier were contained, and thus a moisture permeability at 40° C. and 90% RH of 50 g/m²·day or less and an adhesive force of 20 N/25 mm or more were exhibited. Also, satisfactory results were obtained in the evaluations of holding force and dark spots.

In Example 12, 80% by mass of an ethylene/α-olefin/non-conjugated diene copolymer and 20% by mass of a tackifier were contained, and thus a moisture permeability at 40° C. and 90% RH of 50 g/m²·day or less and an adhesive force of 10 N/25 mm or more were exhibited. Also, satisfactory results were obtained in the evaluations of holding force and dark spots.

On the contrary, in Comparative Example 1, adhesive force was low because the specimen contained only 5% by mass of a tackifier, and the specimen fell off in the holding force test, while dark spots were generated. In Comparative Examples 2 and 3, since the specimens did not contain any tackifier, the specimens had low adhesive force, the specimens fell off in the holding force test, and dark spots were generated. In Comparative Examples 4 and 5, since the specimens did not contain any tackifier but contained 30% by mass or more of a softening agent, films were not formed, and moisture permeability could not be measured. Other evaluations were carried out by applying the compositions on a substrate; however, the specimens had low adhesive force, the specimens fell off in the holding force test, and dark spots were generated. In Comparative Examples 6 and 7, since 75% by mass of a tackifier was contained, flexibility of the film was insufficient, and thus the specimens could not be pasted to glass, and the tests for adhesive force, holding force, and dark spots could not be carried out.

Having described our invention as related to the present embodiments, it is our intention that the invention not be limited by any of the details of the description, unless otherwise specified, but rather be construed broadly within its spirit and scope as set out in the accompanying claims.

### REFERENCE SIGNS LIST

1 Organic light emitting device
2 Glass substrate
3 Organic light emitting unit
4 Vapor-deposited thin film
5 Sealing film
6 Sealing glass plate
7 Electrodes

1. A sealant composition being adhesive for used in electronic devices, the sealant composition comprising an olefin-based polymer and a tackifier, wherein the olefin-based polymer is at least one selected from an ethylene/α-olefin copolymer and an ethylene/α-olefin/non-conjugated diene copolymer, and the content of the tackifier is 10% by mass or more and 70% by mass or less in the resin composition that constitutes the sealant composition.

2. A sealant composition having adhesiveness for used in electronic devices, the sealant composition comprising an olefin-based polymer and a tackifier, wherein the olefin-based polymer is at least one selected from an ethylene/α-olefin copolymer and an ethylene/α-olefin/non-conjugated diene copolymer, and the content of the tackifier is 40% by mass or more and 70% by mass or less in the resin composition that constitutes the sealant composition.

3. The sealant composition according to claim 1, wherein the tackifier is hydrogenated.

4. The sealant composition according to claim 1, wherein a hydrogenated tackifier is used as the tackifier which is a resin obtained by hydrogenating a petroleum resin containing a cyclic structure.

5. The sealant composition according to claim 1, wherein the ethylene/α-olefin copolymer and the ethylene/α-olefin/non-conjugated diene copolymer have a functional group selected from a carboxyl group, a hydroxyl group, an epoxy group, an amino group, an alkoxysilyl group, a sulfonic acid group, and a nitrile group.

6. The sealant composition according to claim 1, further comprising a softening agent.

7. The sealant composition according to claim 6, comprising:
(a) 10% to 35% by mass of the olefin-based polymer;
(b) 50% to 75% by mass of the tackifier; and
(c) 10% to 30% by mass of the softening agent,
relative to the total mass of the resin composition that constitutes the sealant composition.

8. The sealant composition according to claim 7, wherein the softening agent is formed from a compound of which carbon number of the saturated hydrocarbon chain occupies 50% or more of the total carbon number.

9. The sealant composition according to claim 8, wherein the compound of which carbon number of the saturated hydrocarbon chain occupies 50% or more of the total carbon number is a compound containing an isobutylene skeleton as a main component.

10. The sealant composition according to claim 1, wherein the number average molecular weight of the softening agent is 300 or more and 2000 or less.

11. The sealant composition according to claim 1, further comprising a desiccant.

12. The sealant composition according to claim 1, which is transparent in the visible region at 400 nm to 800 nm.

13. A sealing film formed from the sealant composition according to claim 1, or a sealing sheet having a peelable film laminated on one surface or on either surface of the sealing film.

14. An organic light emitting device comprising a light emitting unit and the sealant composition according to claim 1 on and/or around the light emitting unit, wherein the light emitting unit has a pair of electrode layers facing each other and an organic light emitting layer disposed between the electrode layers.
